(19) United States
(12) Patent Application Publication
(10) Pub. No.: US 2015/0179925 A1
(43) Pub. Date: Jun. 25, 2015

(54) MAGNETIC MULTILAYER STACK

(71) Applicants: IMEC VZW, Leuven (BE); Katholieke Universiteit Leuven, Leuven (BE)

(72) Inventors: Taiebeh Tahmasebi, Singapore (SG); Mauricio Manfrini, Leuven (BE); Sven Cornelissen, Bree (BE)

(21) Appl. No.: 14/575,743

(22) Filed: Dec. 18, 2014

(30) Foreign Application Priority Data
Dec. 18, 2013 (EP) 13197939.5
Jan. 27, 2014 (EP) 14152599.8

(51) Int. Cl. H01L 43/10; H01L 27/22; H01L 43/12; H01L 43/08

(52) U.S. Cl. CPC H01L 43/10; H01L 43/08; H01L 27/222; H01L 43/12

(57) ABSTRACT

A magnetic multilayer stack for a magnetoresistance device and a method of forming the multilayer stack is disclosed. In one aspect, the magnetic multilayer stack comprises a composite soft layer having a non-magnetic layer sandwiched between a first magnetic layer formed of CoFeBN and a second magnetic layer formed of CoFeB.

### CROSS-REFERENCE TO RELATED APPLICATIONS

This application claims foreign priority to European patent application EP 13197939.5, filed Dec. 18, 2013, and to European patent application EP 14152599.8, filed Jan. 27, 2014. The contents of each are incorporated by reference herein in their entireties.

### BACKGROUND

1. Field

The disclosed technology generally relates semiconductor devices and more particular to a magnetoresistance device and a method of forming the magnetoresistance device which includes a magnetic multilayer stack.

2. Description of the Related Technology

Magnetic random access memory (MRAM) is emerging as an alternative to conventional semiconductor memories such as static random access memory (SRAM), dynamic random access memory (DRAM) and flash memory. Unlike SRAM and DRAM, MRAM can advantageously be non-volatile (e.g., data retention of >10 years). In addition, compared to flash memory used for data storage applications, MRAM can have very high endurance (e.g., greater than 10⁶ cycles of memory access, e.g., write access). In addition, compared to flash memory, MRAM devices can advantageously have short access (e.g., read access and write access) times.

In order to be commercially competitive against flash memory, it is desirable to increase the density of the MRAM cells in a chip, which may involve keeping the MRAM cells as small as possible. Further, in order to be commercially competitive against SRAM and/or DRAM, it is desirable to increase the speed of operation of the MRAM cell without compromising the density. Furthermore, it is also desirable to achieve low current switching for the MRAM cell without compromising thermal stability.

Memory elements for MRAMs may include giant magnetoresistive (GMR) spin valves (SV). The GMR-SV may include two ferromagnetic layers separated by a non-magnetic metallic spacer (or barrier) layer.

However, a greater magnetoresistance (MR) than that typically observed for GMR-SV has been observed in devices known as magnetic tunnel junction (MTJ) devices, where tunnelling magnetoresistance (TMR) occurs due to the presence of an insulator layer as spacer layer or a barrier layer between ferromagnetic layers (e.g., between a soft ferromagnetic layer, also referred to as a free layer, and a hard ferromagnetic layer, also referred to as a fixed layer), instead of a metallic spacer (or a barrier) layer. As used herein, a soft ferromagnetic layer refers to a ferromagnetic layer that undergoes a current-induced magnetization switching (CIMS), while a hard ferromagnetic layer refers to a ferromagnetic layer that does not undergo a CIMS. The MTJ devices can be used in MRAM devices, where the difference in the magnetic resistance between two remnant states can be used to represent digital bits 0 and 1.

Spin-torque transfer based MRAMs (STT-MRAMs) can be scalable to very small sizes as compared to field-switchable MRAM devices. A magnetic layer of an STT-MRAM can have a magnetic anisotropy that is either generally parallel or generally perpendicular relative to a plane of the magnetic layer, e.g., a plane of a major surface or a major interface of the magnetic layer. Thus, in STT-MRAMs where electrons tunnel through a barrier in a direction generally perpendicular to the plane of the magnetic layers, the anisotropy direction can be either generally perpendicular or generally parallel to the electron tunnelling direction. STT-MRAM devices having magnetic layers with perpendicular magnetic anisotropy (PMA) may have several advantages over STT-MRAM devices with conventional in-plane magnetized layers such as improved thermal stability, scalability and reduced spin transfer torque (STT) switching currents.

A STT-MRAM device typically comprises a magnetic tunnel junction (MTJ) element which comprises a tunneling spacer (or barrier layer) sandwiched in between a ferromagnetic hard layer (comprising a fixed magnetic layer and a pinning layer) and a ferromagnetic soft layer (or also often referred to as ‘free layer’). The direction of magnetization of the hard layer is fixed and therefore the hard layer does not undergo a current-induced magnetization switching (CIMS), whereas the direction of magnetization of the soft layer can be changed by passing a drive current through, and therefore the soft layer can undergo a CIMS. Without being bound to any theory, CIMS is believed to occur in the soft layer when it receives current that is spin-polarized by the magnetization of the hard layer. When the direction of magnetization of the hard layer and the soft layer are parallel, the MTJ element is in a low resistance. When the direction of magnetization of the hard layer and the soft layer are antiparallel the MTJ element is in a high resistance. For a bottom pinned MTJ stack, the bottom ferromagnetic layer refers to the hard layer and the top ferromagnetic layer refers to the soft layer. For a top pinned MTJ stack, the bottom ferromagnetic layer refers to the soft layer and the top ferromagnetic layer refers to the hard layer.

For an STT-MRAM with a perpendicular geometry, materials with a high PMA such as multilayers of Co/Pd or Co/Pt or Co/Ni on the one hand and FePt or CoPt on the other hand in their chemically ordered phase (L10 phase) are considered as potential candidates. These materials are mainly preferred to be used as hard layer in the MTJ stack of MRAM devices, i.e. a magnetic layer which retains its magnetization direction during the operation of the device. Their use as the soft layer (or free layer or storage layer) in the MTJ stack is questionable. The soft layer comprises a magnetic layer/layers for which the magnetic polarization is switched during the operation of the MTJ based device.

Due to characteristics such as relative ease of device fabrication, relatively high anisotropy, relatively low switching current and relatively high tunnelling magnetoresistance (TMR), a potential MTJ candidate that has been suggested for an STT-MRAM cell is the CoFeB-MgO based MTJ with PMA. A CoFeB-MgO based MTJ comprises a soft layer (or free layer or storage layer) comprising CoFeB, a hard layer and a tunnelling barrier (or spacer layer) of MgO sandwiched between the hard layer and the soft layer. The anisotropy of the reported material can support a device diameter of about 35 nm, limited mainly by the maximum thickness of about 1.3 nm and maximum effective anisotropy (K_{eff}.t) about 0.25 erg/cm².

There is, however, a need to improve the magnetic properties of the magnetic materials, and in particular to improve the performance of magnetoresistance devices, specifically to reduce the damping constant which leads to reducing the switching current of STT-MRAM devices.

### SUMMARY OF CERTAIN INVENTIVE ASPECTS

An object of the present disclosure is to provide an improved magnetic multilayer stack for a magnetoresistance device. A further object is to provide an improved magnetoresistance device. This is achieved by providing a composite soft (or free or storage) layer in a multilayer magnetic stack with higher thickness, a reduced magnetic moment and an improved anisotropy compared to the prior art.

According to a first aspect, a magnetic multilayer stack for a magnetoresistance device is disclosed, the magnetic multilayer stack comprises a composite soft layer, the composite soft layer comprises a first magnetic layer, having a perpendicular magnetic anisotropy, comprising cobalt-iron-boron-nitride (CoFeBN) and; a second magnetic layer, having a perpendicular anisotropy, comprising cobalt-iron-boron (CoFeB) or a combination of cobalt-iron-boron (CoFeB) with cobalt (Co) or iron (Fe) and a non-magnetic layer sandwiched in between the first and the second magnetic layer, the non-magnetic layer comprising any of Ta, Ti, Hf, Cr, Cr, Ru, V, Ag, Au, W, TaN, TiN, RuO, Zr or a combination thereof.

According to embodiments of the first aspect, the magnetic multilayer stack further comprises a tunnelling barrier layer at one side of the stack close to the second magnetic layer, the tunnelling barrier layer comprising a non-magnetic metallic material or an insulator material.

According to embodiments of the first aspect, the magnetic multilayer stack further comprises a spacer layer at the other side of the stack close to the first magnetic layer, the spacer layer comprising a non-magnetic metallic material or an insulator material.

According to embodiments of the first aspect, the insulator material comprises an oxide selected from the group consisting of magnesium oxide, magnesium-titanium oxide, magnesium-aluminium oxide or aluminium oxide. This is advantageous as a magnetic multilayer structure is provided which may be used in a magnetic tunnel junction (MTJ). Moreover, the multilayer stack may be used in a double barrier magnetic tunnel junction (MTJ) structure which for instance allows for improved spin torque switching of the tunnelling currents in the MTJ device and improved anisotropy.

According to embodiments of the first aspect, the non-magnetic metallic material comprises any of Cu, Cr or Ru. This is advantageous as a magnetic multilayer structure is provided which may be used in a GMR device, specifically for read head sensor applications.

According to embodiments of the first aspect, the magnetic multilayer stack further comprises a hard layer close to and at the other side of the tunnelling barrier layer. The tunnelling barrier layer is thus sandwiched in between the hard layer and the second magnetic layer of the composite soft layer.

According to embodiments of the first aspect, the hard layer comprises a bilayer of a magnetic layer (such as Co, Fe, Ni, CoFeB or combination of thereof) with a layer of a non-magnetic material (such as Pt or Pd) or a bilayer of Co/Ni or comprises an alloy formation of FePt or CoPt, in their chemically ordered L10 phase, with perpendicular magnetic anisotropy.

According to embodiments of the first aspect, the boron concentration of the cobalt-iron-boron-nitride is in the range of 10-30 atomic percentage.

According to embodiments of the first aspect, the first magnetic layer and/or the second magnetic layer have a thickness in the range of 0.6-2 nm.

According to embodiments of the first aspect, the non-magnetic layer has a thickness in the range of 0.2-2.5 nm.

According to embodiments of the first aspect, the tunnelling barrier layer has a thickness in the range of 0.8-2.5 nm.

According to embodiments of the first aspect, the spacer layer has a thickness in the range of 0.4-2.5 nm.

According to embodiments of the first aspect, the spacer layer has a smaller effective thickness than the tunnelling barrier layer. The resistance-area product (RA) of the spacer layer should be lower than the resistance-area product (RA) of the tunnelling barrier layer.

The spacer layer and the tunnelling barrier layer may both comprise the same material, such as for example MgO.

According to embodiments of the first aspect, the first, the second magnetic layer and the non-magnetic layer may have the same thickness.

A magnetoresistive device is also disclosed comprising a magnetic multilayer stack sandwiched between a bottom electrode and a top electrode, the magnetic multilayer stack according to any of the embodiments of the first aspect.

According to a second aspect, a magnetoresistance device is disclosed, the magnetoresistance device comprises a bottom electrode, the bottom electrode comprising an upper seed layer, a first magnetic structure on the seed layer; the first magnetic structure being a soft layer or a hard layer,; a tunnel barrier structure on the first magnetic structure; the tunnel barrier layer comprising a non-magnetic metallic material or an insulator material, a second magnetic structure on the tunnel barrier structure; the second magnetic structure being a hard layer in case the first magnetic structure is the composite soft layer or the second magnetic structure being a soft layer in case the first magnetic structure is the hard layer, and a top electrode on the second magnetic structure, characterized in that: the soft layer of the first or the second magnetic structure is a composite structure comprising a first magnetic layer, having a perpendicular magnetic anisotropy comprising cobalt-iron-boron-nitride (CoFeBN); a second magnetic layer, having a perpendicular anisotropy, comprising cobalt-iron-boron (CoFeB) or Co or Fe or a combination thereof the second magnetic layer being located close to the tunnel barrier structure, and a non-magnetic layer sandwiched in between the first and the second magnetic layer, the non-magnetic layer comprising any of Ta, Ti, Hf, Cr, Cr, Ru, V, Ag, Au, W, TaN, TiN, RuO, Zr or a combination thereof.

According to embodiments of the second aspect, the magnetoresistance device further comprises a spacer layer close to the first magnetic layer, the spacer layer comprising a non-magnetic metallic material or an insulator material.

According to embodiments of the second aspect, the insulator material comprises an oxide selected from the group consisting of magnesium oxide, magnesium-titanium oxide, magnesium-aluminium oxide or aluminium oxide. This is advantageous as a magnetic multilayer structure is provided which may be used in a magnetic tunnel junction (MTJ). Moreover, the multilayer stack may be used in a double barrier magnetic tunnel junction (MTJ) structure which for instance allows for improved switching of the tunnelling currents in the MTJ device.

According to embodiments of the second aspect, another hard layer is provided in contact with the spacer layer. The spacer layer is thus sandwiched in between the another hard layer and the first magnetic layer. It is an advantage that a dual MTJ stack may be provided.

According to embodiments of the second aspect, the non-magnetic metallic material comprises any of Cu, Cr or Ru. This is advantageous as a magnetic multilayer structure is provided which may be used in a GMR device, specifically for read head sensor applications.

According to embodiments of the second aspect, the hard layer comprises a bilayer of magnetic layer (such as Co, Fe, Ni, CoFeB or combination of thereof) with a non-magnetic materials (such as Pt or Pd) or Co/Ni or alloy formation of FePt or CoPt with perpendicular magnetic anisotropy.

According to embodiments of the second aspect, the boron concentration of the cobalt-iron-boron-nitride is in the range of 10-30 atomic percentage.

According to embodiments of the second aspect, the first magnetic layer and/or the second magnetic layer have a thickness in the range of 0.6-2 nm.

According to embodiments of the second aspect, the non-magnetic layer has a thickness in the range of 0.2-2.5 nm.

According to embodiments of the second aspect, the tunnelling barrier layer has a thickness in the range of 0.8-2.5 nm.

According to embodiments of the second aspect, the another tunnelling barrier layer has a thickness in the range of 0.4-2.5 nm.

According to embodiments, the first 110, second 130 magnetic layer and the non-magnetic layer 120 may have the same thickness.

It is an advantage that the combination of the first and second magnetic layer and the non-magnetic layer according allows for a larger effective thickness of the magnetic multilayer stack and an improved PMA. Hence, an improved PMA may be obtained while mitigating problems associated with increased in-plane anisotropy as the thickness of the magnetic layer is increased.

It is an advantage that the combination of the first and second magnetic layer and the non-magnetic layer allows for a larger effective thickness of the magnetic multilayer stack such that both thermal stability and anisotropy of the multilayer stack may be improved, without sacrificing the PMA.

Further features of, and advantages with, the present disclosure will become apparent when studying the appended claims and the following description. The skilled person will realize that different features of the present disclosure may be combined to create embodiments other than those described in the following, without departing from the scope of the present disclosure.

### BRIEF DESCRIPTION OF THE DRAWINGS

The above aspects of the present disclosure will now be described in more detail, with reference to the enclosed drawings showing embodiments of the disclosure.

FIG. 1 illustrates a composite soft layer according to an embodiment of the present disclosure.

FIG. 2 illustrates a magnetoresistance device according to an embodiment of the present disclosure.

FIG. 3 illustrates a magnetic multilayer stack according to an embodiment of the present disclosure.

FIG. 4 illustrates normalized magnetic moment plotted against applied magnetic field for the magnetic multilayer stack according to embodiments of the present disclosure.

FIG. 5 illustrates a magnetoresistance device according to an embodiment of the present disclosure.

FIG. 6 illustrates a dual MTJ magnetoresistance device according to an embodiment of the present disclosure.

### DETAILED DESCRIPTION OF CERTAIN ILLUSTRATIVE EMBODIMENTS

The present disclosure will now be described more fully hereinafter with reference to the accompanying drawings, in which currently preferred embodiments of the disclosure are shown. This disclosure may, however, be embodied in many different forms and should not be construed as limited to the embodiments set forth herein. These embodiments are rather provided for thoroughness and completeness, and for fully conveying the scope of the disclosure to the skilled person.

The present disclosure and accompanying drawings will be described in view of top pinned Magnetic Tunnel Junction (MTJ) stack. It is clear for a person skilled in the art that the appropriate layers may be interchanged as such forming the reversed stack, i.e. a bottom pinned MTJ stack. The wording ‘perpendicular magnetic anisotropy’ (PMA) is to be understood as that the magnetic field is mainly oriented perpendicular to the layer, i.e. parallel to the surface normal of the layer. The PMA is induced by the surface of the layer, i.e. by interface effects of a magnetic material. It should be noted that for thicker, in other words bulk-like, layers of magnetic material in-plane anisotropy is the dominating magnetic orientation in the layer, i.e. the magnetic field is mainly oriented parallel to the layer. Accordingly, the in-plane anisotropy will normally overcome the PMA when the thickness of the magnetic layer is increased.

In order to increase the performance of magnetoresistive devices, e.g. increased density and reduced dimensions of the devices, improved magnetic multilayer stacks are needed. One way to achieve this is to increase the perpendicular magnetic anisotropy (PMA) of the multilayer stack.

According to a first aspect of the present disclosure, a magnetic multilayer stack comprising a composite soft layer is provided in order to improve the conventional type of soft layer in which a single layer of CoFeB is used. The magnetic multilayer (composite) stack comprises at least two magnetic layers separated by a non-magnetic layer. A first magnetic layer is formed of a cobalt-iron-boron-nitride (CoFeBN) material, e.g., a CoFeBN alloy. The first magnetic layer has a perpendicular magnetic anisotropy (PMA). A second magnetic layer is formed of a cobalt-iron-boron (CoFeB) material, e.g., a CoFeB alloy, or a combination or a mixture of CoFeB with Co or Fe. The second magnetic layer has a perpendicular magnetic anisotropy. The sandwiched non-magnetic layer comprises any of Ta, Ti, Hf, Cr, Ru, V, Ag, Au, W, TaN, TiN, RuO, Zr or a combination thereof. The first 110 magnetic layer and the second 130 magnetic layer may also be referred to as analyzer layer. As used herein, a material or an alloy designated by its constituent elements without a specified composition can have any concentration of each of the constituent elements. For example, a CoFeBN alloy can have concentrations of each of Co, Fe, B and N that is between zero and 100 atomic percent.

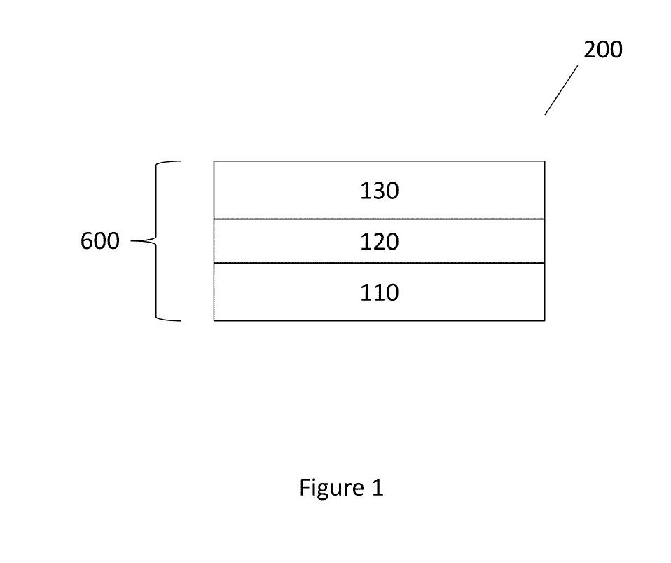

FIG. 1 schematically shows such a composite soft layer 600, comprising a non-magnetic layer 120 sandwiched in between a first magnetic layer 110 and a second magnetic layer 130 according a first aspect.

The magnetic multilayer stack 600 may thus for example comprise a CoFeB/Ta/CoFeBN composite structure. By using a magnetic layer comprising CoFeBN, the PMA of the magnetic layer is improved. Without being bound to any theory, the Ta layer may absorb boron from the CoFeBN layer, thereby reducing the boron composition in CoFeBN, e.g., during optional annealing steps executed during fabrication of the magnetic multilayer structure. As a result, the PMA of the magnetic layer is improved. The boron concentration of the cobalt-iron-boron nitride is in the range of 10-30 atomic percentage which is advantageous in that the PMA is improved. By tuning the thicknesses of the respective layers used in the stack, the characteristics of the stack may be optimized to e.g. fit specific needs.

Without being bound to any theory, it is believed that PMA is induced at the surface of the layer, e.g., by interface effects of a magnetic material. It should be noted that for thicker (bulk-like) layers or structures of the magnetic material, in-plane anisotropy is the dominating magnetic orientation in the layer, i.e. the magnetic field is mainly oriented parallel to the layer. Thus, magnetic layer 110 according to this embodiment has a physical thickness that is sufficiently thin to display PMA. For example, the thickness is between about between about 0.6 nm and about 2 nm, between about 0.8 and about 1.8 nm, between about 1.0 nm and about 1.6 nm, for instance about 1.1 nm. Inventors have found that having one of these particular thickness ranges provides PMA that is greater than the in-plane anisotropy for the magnetic layer 110.

By introducing a non-magnetic layer 120 between a first magnetic layer 110 comprising CoFeBN and a second magnetic layer 130 comprising CoFeB or a combination CoBeF with Co or Fe, the two magnetic layers 110, 130 may be magnetically coupled. The non-magnetic layer comprises or consists of Ta, Ti, Hf, Cr, Ru, V, Ag, Au, W, TaN, TiN, RuO, Zr or a combination thereof. In this configuration, the first magnetic layer 110 comprising cobalt-iron-boron-nitride is preferably positioned further away from the insulating tunnel barrier layer (such as for example a MgO layer). By inserting a non-magnetic layer 120 in between the two magnetic layers 110, 130, the effective thickness of the composite structure 600 may thereby be increased while the problems associated to the in-plane anisotropy are mitigated.

As used herein, the phrase wording ‘magnetically coupled’ refers to circumstances where a coupling strength of one magnetic layer to an additional magnetic layers in a composite structure is large enough such that the first and additional magnetic layers, e.g., the two magnetic layers 110, 130 described with respect to FIG. 1, although separated by the non-magnetic layer 120, behave as a single magnetic layer. Hence, an effectively thicker magnetic layer comprising a CoFeBN/Ta/CoFeB composite structure may be obtained which improves the thermal stability and anisotropy of the multilayer stack without sacrificing the advantages of PMA. The PMA and thermal stability of the magnetic multilayer stack (composite structure) can thus be increased while the problems associated to the in-plane anisotropy can be alleviated as the volume of each magnetic layer can be kept sufficiently small.

It should be noted that the effective thickness is increased when the magnetic layers 110, 130 are magnetically coupled to each other. This condition is fulfilled if the thickness of the intermediate non-magnetic layer 120 is sufficiently thin. The thickness of the non-magnetic layer 120 is preferably in the range between about 0.2 nm and about 4 nm, between about 0.2 nm and about 3 nm, or between about of 0.2 nm and about 2.5 nm, as these thicknesses provides efficient magnetic coupling. It is noted that if the non-magnetic layer 120 is too thin, e.g., less than 0.2 nm, it may diffuse through the magnetic layers 110, 130 after annealing and as such deteriorating the positive effect of magnetic coupling between the magnetic layers 110, 130.

According to another embodiment, one or both of the first magnetic layer 110 and the second 130 magnetic layer has a thickness in the range between about between about 0.6 nm and about 2 nm, between about 0.8 and about 1.8 nm, between about 1.0 nm and about 1.6 nm, for instance about 1.1 nm.

According to embodiments, each of the first magnetic layer 110, the second magnetic layer 130 and the non-magnetic layer 120 has approximately the same thickness.

It should be noted that the number of layers in the stack may affect the thermal stability of the magnetic material. When the number of layers in the stack is larger, the magnetic material becomes thicker and is hence more stable.

In embodiments of this disclosure, one or both of the CoFeB material (or alloy) and the CoFeBN material (or alloy) is formed by sputtering a single target having a composition represented as CoₓFe_{y}B_{z} (with 10<=x,y<=70, 10<=z<=30). In other embodiments, the CoFeBN material is formed by co-sputtering multiple targets such that a ratio of sputtered atoms of Co, Fe and B arriving at a substrate surface has a composition represented by CoₓFe_{y}B_{z}, where 10<=x,y<=70 and 10<=z<=30. Both CoFeBN and CoFeB materials may be sputtered in a chamber that contains one or more inert gases, e.g., Ar. Unlike the CoFeB material, however, the CoFeBN material may be formed by sputtering in a chamber that contains nitrogen gas introduced therein during the sputtering process, during which the nitrogen atoms are incorporated to form the CoFeBN material. The nitrogen flow rate could vary between 1 sccm to 15 sccm. In one embodiment, the CoₓFe_{y}B_{z} target composition is Co₂₀Fe₆₀B₂₀ and nitrogen flow rate could is preferably 1 sccm or 3 sccm. In another embodiment of this disclosure, the CoₓFe_{y}B_{z} target composition is Co₆₀Fe₂₀B₂₀, while nitrogen flow rate is preferably 1 sccm or 3 sccm.

In embodiments, the composition of the CoFeBN material is represented by the chemical formula (Co₃₃Fe₆₇)_{100-x-y}BₓN_{y} (with 10<=x<=30 and 1<=y<=10).

According embodiments, the non-magnetic layer 120 is preferably made of a material that can absorb boron from at least one of CoFeB or CoFeBN layers. For instance, a tantalum (Ta) layer may absorb boron from the CoFeB or CoFeBN layer by thermal diffusion to reduce the amount of boron in CoFeB or CoFeBN, e.g., during the annealing steps used when fabrication the magnetic multilayer structure. Thus, according to embodiments, while the non-magnetic layer 120 as-deposited does not contain B, B may be present in a final device, or in an intermediate structure that has received an annealing treatment, after formation of the composite structure 600 at a temperature between room temperature and about 400° C., between about 100° C. and about 350° C. or between about 150° C. and about 300° C. Inventors have found that incorporating B into the non-magnetic layer results in an improvement of the PMA of the magnetic layer. According to embodiments, B is thermally diffused into the nonmagnetic layer such that the nonmagnetic layer has a B concentration that is greater than about 0.1%, between about 0.1% and about 5% by atomic percent, or between about 0.1% and about 1% by atomic percent.

In some embodiments, the first magnetic layer 110 and the second magnetic layer 130 are sputtered in the same sputtering chamber. In some embodiments, the first magnetic layer 110, the non-magnetic layer 120 and the second magnetic layer 130 are formed in-situ in a single sputtering chamber.

According to embodiments, the multilayer stack 200 may comprise a repetition of the composite structure 600. By repetition of the composite structure 600 comprising a non-magnetic layer 120 sandwiched in between a first magnetic layer 110 and second magnetic layer 130, it is possible to provide a magnetic multilayer stack 600 with a higher effective thickness in which the repeated magnetic layers 110, 130 are magnetically coupled. The effective thickness of the magnetic layers is thereby increased such that the thermal stability and the PMA of the multilayer stack are improved.

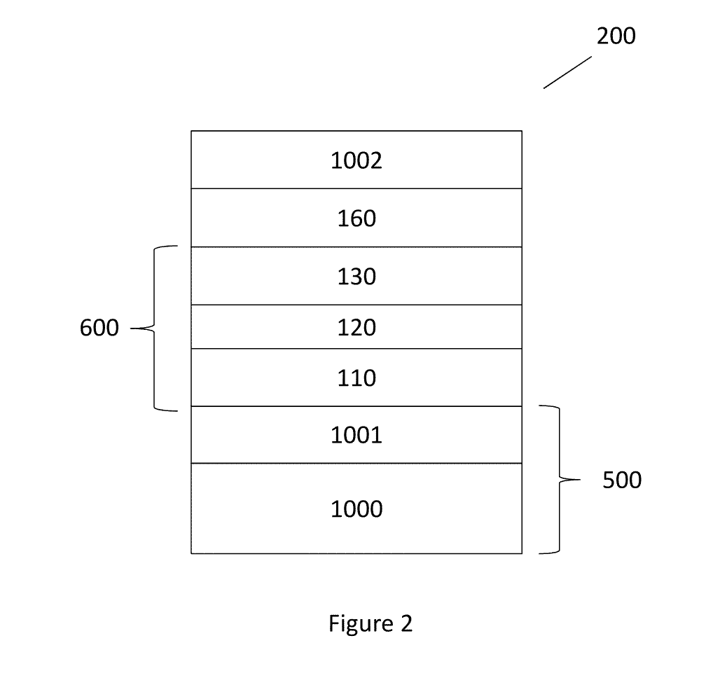

The multilayer magnetic stack 200 may further comprise a tunnelling barrier layer 160 at one side close to the second magnetic layer 130, the tunnelling barrier layer comprising a non-magnetic metallic material or an insulator material. FIG. 2 schematically shows such a configuration thereby showing the bottom electrode 500, comprising a substrate 1000 and optional seed layer 1001, and a hard layer 1002. The composite soft layer 600 according to embodiments is thus sandwiched in between the bottom electrode 500 and the tunnelling barrier layer 160. The first magnetic layer 110 comprising CoFeBN should be located further away from the tunnelling barrier layer 160 than the second magnetic layer 130. For a magnetic tunnel junction (MTJ) stack, the tunnelling barrier layer 160 comprises an oxide selected from the group consisting of magnesium oxide, magnesium-titanium oxide, magnesium-aluminium oxide or aluminium oxide. For giant magneto resistor (GMR) stack the tunnelling barrier layer 160 comprises a non-magnetic metallic material chosen from Cu, Cr or Ru.

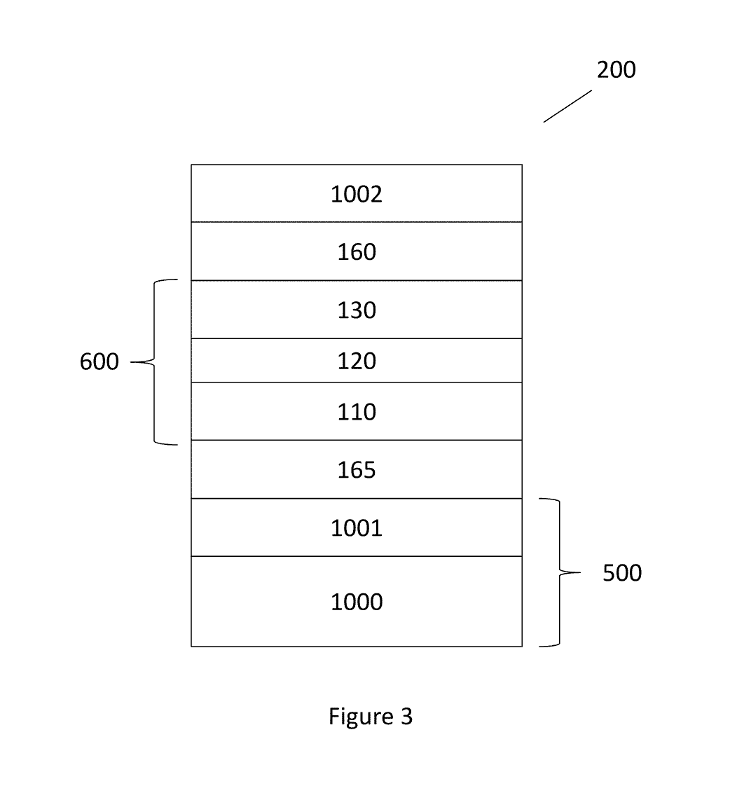

According to embodiments and as schematically shown in FIG. 3, the multilayer stack 200 may further comprise a spacer layer 165 at the other side of the composite structure 600 close to the first magnetic layer 110. The spacer layer 165 comprises a non-magnetic metallic material or an insulator material. The magnetic multilayer stack 200 then has a structure of a double magnetic tunnel junction (DMTJ), which for instance allows for improved switching of the tunnelling currents in a MTJ device. This spacer layer 165 preferably comprises the same material as the tunnelling barrier layer 160. However the thickness of the spacer layer 165 should be much less than the thickness of the tunnelling barrier layer 160. The first magnetic layer 110 is thus located closest to the spacer layer 165, otherwise said closest to the thinnest layer. One may also say that the first magnetic layer 110 should be located the closest to the MgO layer with the lowest resistance area product (RA), i.e. the smallest effective thickness. When using a tunnelling barrier layer and spacer layer comprising MgO, the composite soft layer thus has two MgO interfaces.

It is advantageous to provide a composite magnetic multilayer stack 200 comprising MgO/CoFeBN/Ta/CoFeB/MgO. Such magnetic multilayer stack could be used as storage layer. This storage layer has favourable crystalline structure after post annealing, i.e. atomic lattice matching, and band alignment such that high spin polarization, high tunnelling magnetoresistance (TMR) will be achieved. Moreover, lower Gilbert damping constant was observed in CoFeBN/Ta/CoFeB/MgO stack and consequently low switching currents. An improved MTJ structure may thereby be provided. Such a MTJ stack having two MgO interfaces which show improved PMA with improved spin torque switching current, may moreover be suitable for integration with conventional transistors such as complementary metal-oxide-semiconductor (CMOS), which allows the integration of STT-MRAMs into large scale integrated circuits.

It should further be noted that in the MgO/CoFeBN/Ta/CoFeB/MgO system mainly the two MgO interfaces improve the overall interface anisotropy in such stack and thus also reduce the switching current. It is mainly the proper choice for the first magnetic layer 110, comprising CoFeBN, which reduces the Gilbert damping constant affecting the magnetic switching current.

The presence of nitrogen N in the CoFeBN material increases the interface PMA and also acts as a diffusion barrier as compared to using only CoFeB as the magnetic material in the magnetic layers 110, 130. The Ta/CoFeBN interfaces in the magnetic multilayer stack 600 also improve the PMA of the stack 200. The alternating structure of magnetic and non-magnetic layers disclosed for the magnetic multilayer stack 600 provides increased effective thicknesses of the magnetic materials used which lead to an increase in the thermal stability of the magnetic multilayer stack 600 without compromising other important parameters such as PMA and band alignment.

It should be noted that the number of layers in the stack 600 may affect the thermal stability of the magnetic material. When the number of stacks is larger, the magnetic material becomes larger and is hence more stable.

In order to provide high tunnelling probability, the tunnelling barrier material 160 is in the embodiments illustrated by FIGS. 2 and 3 and may have a thickness in the range of 0.8-2.5 nm. Preferably, the tunnel barrier layer is about 1 nm.

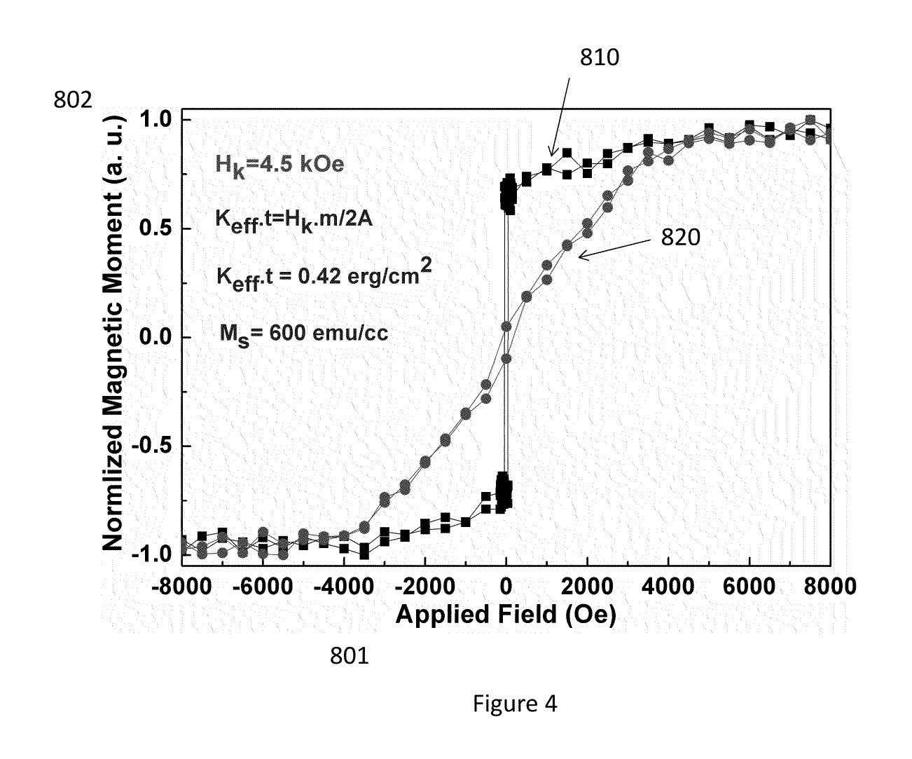

FIG. 4 shows a graph of the normalized magnetic moment 802 in arbitrary units (a.u.) plotted against the applied magnetic field 801 for a magnetic multilayer stack 600 comprising a CoFeBN/Ta/CoFeB composite soft layer 600 according to embodiments of the present disclosure. It shows the magnetic hysteresis (MH). Plot 810 shows the normalized magnetic moment in case of an applied magnetic field that is oriented perpendicular to the magnetic multilayer stack, i.e. a magnetic field orientation perpendicular to the surface of the layers. Plot 820 also shows the normalized magnetic moment in the case of an applied magnetic field that is oriented in-plane of the layers of the magnetic multilayer stack 600. From the data it can be shown that this magnetic multilayer stack exhibits a strong PMA. A strong PMA can thus be achieved by using the composite soft layer structure 600 comprising a layer of CoFeBN. For this experiment, the CoFeBN magnetic layer 110 and the CoFeB magnetic layer 130, both have a thickness of 1.1 nm. A thin layer of Ta of about 1 nm is inserted as a non-magnetic layer 120 in between the two magnetic layers 110,130. The magnetic-multilayer stack 600 shows a magnetic anisotropy field of about 4.5 kOe (Oersted) and an effective anisotropy Keff.t of 0.42 erg/cm². Hence, the magnetic multilayer stack 600 provides increased thermal stability. Moreover, low saturation magnetization (600 emu/cc) is obtained by the magnetic multilayer stack 400 which is important for providing reduced switching currents.

Composite free or soft layers 600, comprising a first layer, exhibiting a lower Ms and a low alpha, and a second layer, exhibiting a high Ks (interface anisotropy) and a high Tunneling Magneto Resistance (TMR) can provide for a lower switching current for the same thermal stability in perpendicular STT-MRAM applications. In this disclosure the first layer 110 comprises CoFeBN. The Nitrogen reduces Ms (saturation magnetization) and lets the magnetic damping unchanged. According to experimental results, implemented in a composite structure 600 comprising CoFeBN/Ta/CoFeB, it maintains a high TMR and adequate RA, which yields a record low alpha for 2 nm of CoFe-based free layer 600 with PMA. The damping factor reduces to 0.0085 for composite layer of CoFeBN/Ta/CoFeB composite freelayer, as compare to 0.015 for single CoFeB soft layer.

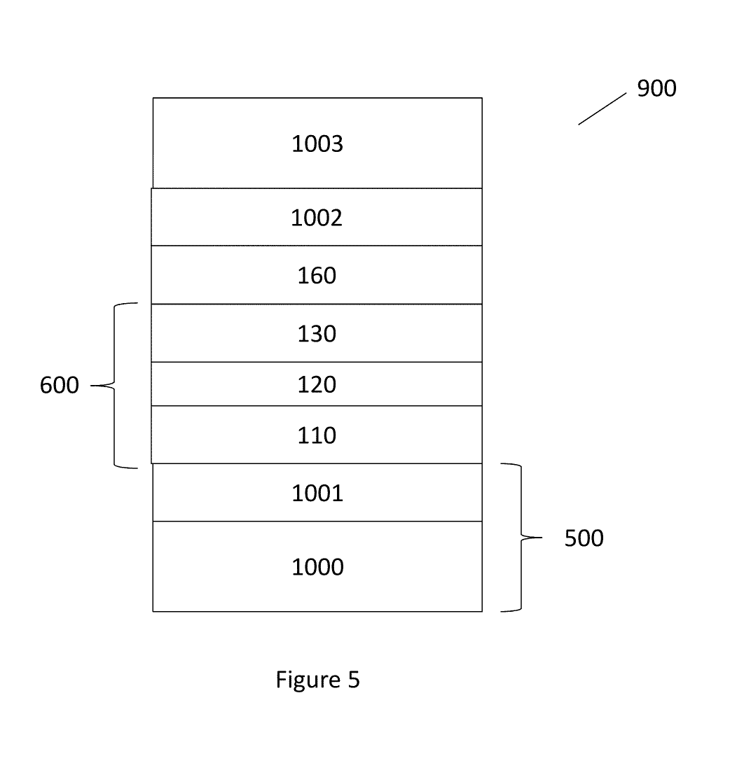

According to a second aspect of the present disclosure, a magnetoresistance device 900 is provided as illustrated by FIG. 5. The magnetoresistance device 900 comprises a composite soft layer 600. The magnetoresistance device comprises a bottom electrode 500, which may comprise a seed layer 1001 formed on a substrate 100,. On the bottom electrode 500 a first magnetic structure 600 is present. In case of a top pinned MTJ as shown in FIG. 5, the first magnetic structure 600 is a soft layer. In case of a bottom pinned MTJ, this first magnetic structure 600 is a hard layer. On the first magnetic structure 600, a tunnel barrier structure 160 is present, whereby the tunnel barrier layer 160 comprises a non-magnetic metallic material or an insulator material. A second magnetic structure 1002 is present on the tunnel barrier structure 160. In case of a top pinned MTJ as shown in FIG. 5, the second magnetic structure 1002 is a hard layer. In case of a bottom pinned MTJ, the first magnetic structure 600 is the hard layer and the second magnetic structure is a soft layer. A top electrode 1003 is present on the second magnetic structure 1002.

The soft layer in a the MTJ is a composite structure 600 comprising a first magnetic layer 110, having a perpendicular magnetic anisotropy and comprises cobalt-iron-boron-nitride (CoFeBN) ; a second magnetic layer 130, having a perpendicular anisotropy and comprising cobalt-iron-boron (CoFeB) or Co or Fe or a combination thereof whereby; the second magnetic layer 130 is located close to the tunnel barrier structure 160, and a non-magnetic layer 120 sandwiched in between the first magnetic layer 110 and the second magnetic layer 130., The non-magnetic layer 120 comprises any of Ta, Ti, Hf, Cr, Ru, V, Ag, Au, W, TaN, TiN, RuO, Zr or a combination thereof. This is advantageous as a magnetic multilayer stack 600 is provided which may be used in a magnetic tunnel junction (MTJ). The first magnetic layer 110 can have a thickness in the range of 0.6 nm to about 2 nm.

As said in the previous paragraph, the magnetoresistance device 900 may include a seed layer structure 1001. The seed layer 1001 includes at least one layer which may comprise a material selected from the group consisting of titan, vanadium, hafnium, chromium, magnesium oxide, chromium ruthenium, tantalum nitride, titan nitride, and ruthenium oxide. The seed layer 1001 may have a thickness ranging from about 0.1 nm to about 7 nm. The seed layer 1001 may provide a hexagonal close packing (hcp) (002) texture, a face-centered (fcc) (111) texture or a body centered (bcc) (200) texture. The seed layer 1001 may help the first magnetic layer 110 to grow in fcc (111) orientation and thus, achieving PMA in the multilayer stack. A seed layer 1001 having a smaller thickness is desirable for having a more coherent tunnelling through the tunnelling barrier layer 160. PMA may be achieved in the first magnetic layer 110 with a minimum thickness of about 3 nm for the seed layer structure 1001. The magnetoresistance device 900 described provides a low switching current that can be used in spin-transfer torque magnetic random access memory (STT-MRAM). In MRAM applications, the magnetoresistance devices may be part of a memory circuit, along with transistors that provide the read and write currents. The magnetoresistance device 900 may work as or can be part of a multi-level MRAM.

Below and above the tunnelling barrier layer 160 a first and a second spin-polarizing layer may be added (not shown). The first and second spin-polarizing layer preferably comprise Fe, CoFe or CoFeB or a combination thereof. They are arranged at both sides of the tunnelling barrier layer 160 in order to achieve a higher magnetoresistance. The first spin-polarizing layer is then part of the composite soft layer 600, whereas the second spin-polarizing layer becomes part of the hard layer. As such the composite soft layer 600 may comprise for example a CoFeBN/Ta/Fe/CoFeB or a CoFeBN/Ta/CoFeB/Fe stack wherein the Fe layer refers to a first spin-polarizing layer. The thicknesses of the spin-polarizing layers may be varied between about 0.2 nm and about 3 nm to increase the value of the magnetoresistance. At the side of the composite soft layer 600, the spin-polarizing layer may be the same as the second magnetic layer 130.

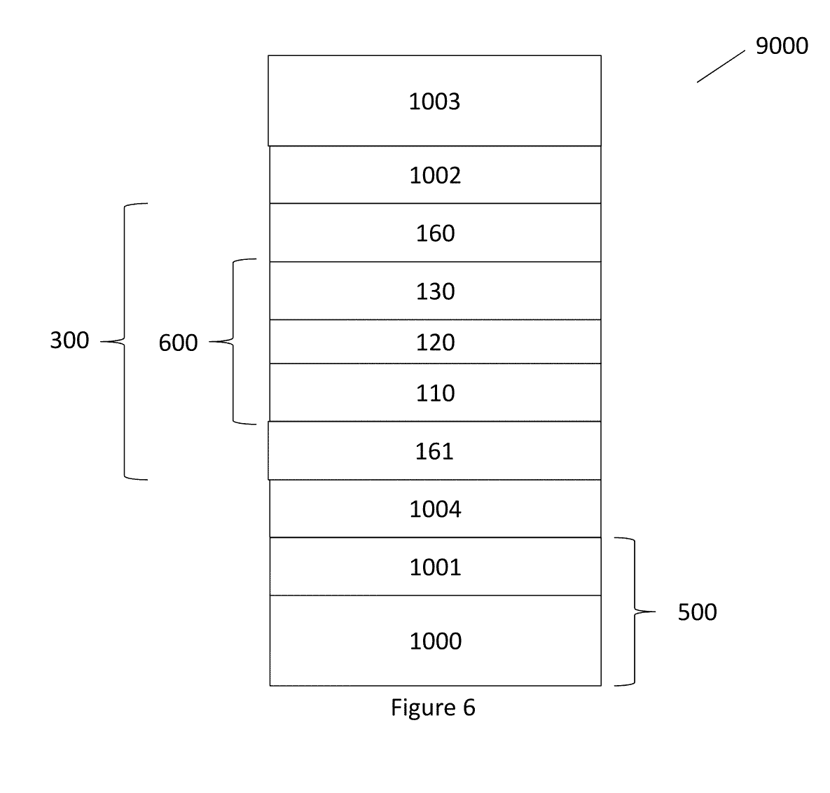

According to embodiments a dual MTJ stack may be provided, i.e. a multilayer stack comprising a composite stack comprising the composite free layer 600 according to different embodiments sandwiched in between two tunnelling barrier layers 160, 161. The composite stack with the two tunnelling barrier layers 160, 161 is sandwiched in between a hard layer 1004 and another hard layer 1002. This is schematically shown in FIG. 6. The composite soft layer 600 comprises a non-magnetic layer 120 sandwiched in between a first magnetic layer 110 and a second magnetic layer 130. The composite soft layer 600 is sandwiched in between a first tunnelling barrier layer 160 and a second tunnelling barrier layer 161. This composite stack 300 is on his turn sandwiched in between a hard layer 1004 and another hard layer 1002. Below the first hard layer 1004 a bottom electrode 500 is provided in order to improve the hard layer anisotropy and above the another hard layer 1002 a top electrode 1003 is provided.

The person skilled in the art realizes that the present disclosure by no means is limited to the preferred embodiments described above. On the contrary, many modifications and variations are possible within the scope of the appended claims.

For example, the barrier layer and the spacer layer may comprise the same, or different materials, selected from the group of magnesium oxide, magnesium-titanium oxide, magnesium-aluminium oxide or aluminium oxide.

Additionally, variations to the disclosed embodiments can be understood and effected by the skilled person in practicing the claimed disclosure, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measured cannot be used to advantage.

What is claimed is:

1. A magnetic multilayer stack for a magnetoresistance device, comprising:
a composite soft layer configured to undergo a current-induced magnetization switching (CIMS), the composite soft layer comprising:
a first magnetic layer having a perpendicular magnetic anisotropy in a direction that is perpendicular to a plane of a major surface of the first magnetic layer, the first magnetic layer formed of a cobalt-iron-boron-nitride (CoFeBN) alloy,
a second magnetic layer formed over the first magnetic layer and having a perpendicular anisotropy in the perpendicular direction, the second magnetic layer formed of a cobalt-iron-boron (CoFeB) alloy, and
a non-magnetic layer interposed between the first magnetic layer and the second magnetic layer, the non-magnetic layer comprising one or more materials selected from the group consisting of Ta, Ti, Hf, Cr, Ru, V, Ag, Au, W, TaN, TiN, RuO and Zr.

2. The magnetic multilayer stack of claim 1, further comprising a tunneling barrier layer formed on a first side of the composite soft layer that is closer to the second magnetic layer, the tunneling barrier layer comprising a non-magnetic metallic material or an insulator material.

3. The magnetic multilayer stack of claim 2, further comprising a spacer layer formed on a second side of the composite soft layer that is closer to the first magnetic layer, the spacer layer comprising a non-magnetic metallic material or an insulator material.

4. The magnetic multilayer stack of claim 2, wherein the insulator material comprises an oxide selected from the group consisting of magnesium oxide, magnesium-titanium oxide, magnesium-aluminium oxide and aluminium oxide.

5. The magnetic multilayer stack of claim 2, wherein the non-magnetic metallic material comprises an element selected from the group consisting of Cu, Cr and Ru.

6. The magnetic multilayer stack of claim 2, further comprising a first hard layer that is configured to not undergo a CIMS and formed on the first side and over the tunneling barrier layer.

7. The magnetic multilayer stack of claim 6, further comprising a second hard layer formed on the second side and over the spacer layer, wherein the spacer layer is interposed between the second hard layer and the first magnetic layer, wherein the spacer layer is configured as a second tunneling barrier layer.

8. The magnetic multilayer stack of claim 1, wherein the CoFeBN alloy has a boron concentration between about 10 atomic percent and about 30 atomic percent.

9. The magnetic multilayer stack of claim 1, wherein at least one of the first magnetic layer and the second magnetic layer has a thickness between about 0.6 nm and about 2 nm.

10. The magnetic multilayer stack of claim 1, wherein the non-magnetic layer has a thickness between about 0.2 nm and about 2.5 nm.

11. The magnetic multilayer stack of claim 1, wherein the tunneling barrier layer has a thickness between about 0.8 nm and about 2.5 nm.

12. The magnetic multilayer stack of claim 3, wherein the spacer layer has a thickness between about 0.4 nm and about 2.5 nm.

13. The magnetic multilayer stack of claim 1, wherein the non-magnetic layer further comprises boron (B) incorporated therein.

14. A magnetoresistance device, comprising:
a bottom electrode comprising a seed layer;
a first magnetic structure formed on the seed layer, wherein the first magnetic structure is configured as one of a soft layer that undergoes a current-induced magnetization switching (CIMS) or a hard layer that does not undergo a CIMS;
a tunnel barrier structure formed on the first magnetic structure, the tunnel barrier structure comprising a non-magnetic metallic material or an insulator material;
a second magnetic structure formed on the tunnel barrier structure, wherein the second magnetic structure is configured as the other of the soft layer or the hard layer; and
a top electrode formed on the second magnetic structure,
wherein one of the first magnetic structure or the second magnetic structure that is configured as the soft layer is a composite structure comprising:
a first magnetic layer having a perpendicular magnetic anisotropy in a direction that is perpendicular to a plane of a major surface of the first magnetic layer, the first magnetic layer formed of a cobalt-iron-boron-nitride (CoFeBN) alloy,
a second magnetic layer formed over the first magnetic layer and having a perpendicular magnetic anisotropy in the perpendicular direction, the second magnetic layer formed of a cobalt-iron-boron (CoFeB) alloy, and
a non-magnetic layer interposed between the first magnetic layer and the second magnetic layer, the non-magnetic layer comprising one or more selected from the group consisting of Ta, Ti, Hf, Cr, Ru, V, Ag, Au, W, TaN, TiN, RuO and Zr.

15. The magnetoresistance device of claim 14, further comprising:
a second tunneling barrier layer formed on a side of the composite structure that is closer to the first magnetic layer; and
a second hard layer interposed by the seed layer and the second tunneling barrier layer.

16. A method of forming a magnetic multilayer stack for a magnetoresistance device, the method comprising:
providing a semiconductor substrate;
forming a first magnetic layer comprising a CoFeBN alloy over the substrate and having a perpendicular anisotropy in a direction perpendicular to a major surface of the first magnetic layer, wherein forming the first magnetic layer comprises sputtering one or more targets that contain cobalt (Co), iron (Fe) and boron (B) while not containing nitrogen (N) in an atmosphere containing nitrogen;
forming a non-magnetic layer on the first magnetic layer, the non-magnetic layer comprising one or more selected from the group consisting of Ta, Ti, Hf, Cr, Ru, V, Ag, Au, W, TaN, TiN, RuO and Zr; and
forming a second magnetic layer comprising a CoFeB alloy on the non-magnetic layer and having a perpendicular anisotropy in the perpendicular direction, wherein forming the second magnetic layer comprises sputtering one or more targets that contain cobalt (Co), iron (Fe) and boron (B).

17. The method of claim 16, further comprising, after forming the first magnetic layer, the non-magnetic layer and the second magnetic layer, thermally diffusing boron (B) atoms into the non-magnetic layer by thermal diffusion from one or both of the first magnetic layer and the second magnetic layer, such that the non-magnetic layer incorporates greater than about 0.1% by atomic percent of B.

18. The method of claim 16, wherein forming one or both of the first magnetic layer and the second magnetic layer comprises co-sputtering multiple targets such that a ratio of sputtered atoms of Co, Fe and B arriving at a substrate surface has a composition represented by CoₓFe_{y}B_{z}, where 10<=x,y<=70 and 10<=z<=30.

19. The method of claim 16, wherein forming one or both of the first magnetic layer and the second magnetic layer comprises sputtering a single target such that a ratio of sputtered atoms of Co, Fe and B arriving at a substrate surface has a composition represented by CoₓFe_{y}B_{z}, where 10<=x,y<=70 and 10<=z<=30.

20. The method of claim 16, wherein sputtering in the atmosphere containing nitrogen comprises flowing between 1 sccm and about 15 sccm of nitrogen gas during sputtering.
